(19) United States
(12) Patent Application Publication
(10) Pub. No.: US 2024/0413098 A1
(43) Pub. Date: Dec. 12, 2024

(54) MULTILAYER MOISTURE REPELLING FILMS FOR FRONT END FET APPLICATIONS

(71) Applicant: Qorvo US, Inc., Greensboro, NC (US)

(72) Inventors: Christo Bojkov, Plano, TX (US); Elias Reese, Dallas, TX (US); Harold Isom, Plano, TX (US); Vivian Li, Richardson, TX (US)

(21) Appl. No.: 18/645,851

(22) Filed: Apr. 25, 2024

Related U.S. Application Data
(60) Provisional application No. 63/499,579, filed on May 2, 2023.

(51) Int. Cl. H01L 23/00; C08G 73/02; C09D 5/16; C09D 179/02; H01L 21/02; H01L 23/29; H01L 23/31

(52) U.S. Cl. CPC H01L 23/564; C08G 73/02; C09D 5/1662; C09D 179/02; H01L 21/02118; H01L 21/02164; H01L 21/02178; H01L 21/0228; H01L 23/293; H01L 23/3171

(57) ABSTRACT

Embodiments of an integrated circuit (IC) structure are disclosed. The IC structure includes a semiconductor substrate having an active region, a contact positioned over the active region, and an Aminated-Polyhydroxy organic (APHO) film that covers the contact. The APHO film prevents moisture from causing shorts and transient currents, thereby allowing high voltages to be applied to the contact.

### RELATED APPLICATIONS

This application claims the benefit of provisional patent application Ser. No. 63/499,579, filed May 2, 2023, the disclosure of which is hereby incorporated herein by reference in its entirety.

### FIELD OF THE DISCLOSURE

This disclosure relates generally to integrated circuit (IC) structures.

### BACKGROUND

Integrated circuit (IC) structures, when operated at a high frequency and high power, perform below expectations due to the presence of moisture entrapped within the materials (i.e., organic and in-organic dielectrics). Moisture often diffuses at higher temperatures (e.g., >50° C.) into the areas of contacts on the semiconductor substrates and the FE devices. In high-power applications, this often leads to electrically shorted circuits. This is particularly problematic when high voltages (e.g., >5V) are being applied to the device contacts. Such areas on the die need to be protected from moisture ingress in order to achieve better performance at high frequencies and lower losses.

### SUMMARY

In some embodiments with an integrated circuit (IC) structure, the structure includes a semiconductor substrate having an active region, a contact positioned over the active region, and an Aminated-Polyhydroxy organic (APHO) film that covers the contact. In some embodiments, the APHO film has a chemical structure of {(—H2N═C . . . (═COH)x . . . }y. In some embodiments, the IC structure further includes a second active region and a second contact, wherein the active region is a first active region, the contact is a first contact, the semiconductor substrate has the second active region, the second contact is formed over the second active region, and the APHO film does not cover the second contact. In some embodiments, the IC structure further includes a third active region and a third contact, wherein the semiconductor substrate has the third active region, the third contact is formed over the third active region, the APHO film does not cover the third contact, and the first active region is positioned between the second active region and the third active region. In some embodiments, the second active region is a first drain/source region, the third active region is a second drain/source region, and the first active region is a channel region. The first active region, the second active region, the third active region, the first contact, the second contact, and the third contact form a field effect transistor (FET), wherein the semiconductor substrate defines a top surface and wherein, with respect to the FET, the APHO film covers approximately only the first contact and portions of the top surface of the channel region, but not the second contact, the third contact, nor other portions of the top surface for the FET. In some embodiments, the first contact is a second metallic contact, the third contact is a second metallic contact, and the first contact is a gate contact. In some embodiments, the first contact is formed on the first active region, the second contact is formed on the second active region, and the third contact is formed on the third active region. In some embodiments, the APHO film exhibits moisture repelling properties of less than 10⁻⁴ grams per square meter per day. In some embodiments, the APHO film has a thickness between 1 to 2 microns. In some embodiments, the APHO film has a thickness of between 1 to 2 microns. In some embodiments, the APHO film has a dielectric constant less than or equal to 2.1. In some embodiments, the APHO film has a transition temperature equal to or greater than 250° C.

In some embodiments, a method of manufacturing an IC structure includes providing a semiconductor substrate that has an active region, providing a contact positioned over the active region, and forming an APHO film that covers the contact. In some embodiments, forming the APHO film that covers the contact includes: (a) performing atomic layer deposition (ALD) to deposit an Al2O3 layer or a silicon dioxide (SiO2) layer; (b) performing molecular layer deposition to deposit a hydroxy-carbon polymer layer. In some embodiments, the method further includes repeating (a) and (b) until the APHO film has a thickness of between 1 to 2 microns. In some embodiments, the active region is a channel region and the contact is a gate contact. In some embodiments, the APHO film further covers a portion of a top surface of the semiconductor substrate over the channel region. In some embodiments, the semiconductor substrate defines a surface, the active region is a channel region, the contact is a gate contact formed over the channel region. In some embodiments, the semiconductor substrate defines a first drain/source region and a second drain/source region; a first drain/source contact is formed over the second drain/source region, a second drain/source contact is formed over the first drain/source region, wherein the channel region is positioned between the first drain/source region and the second drain/source region. The first drain/source region, the first drain/source contact, the second drain/source region, the second drain/source contact, the channel region, and the gate contact form a FET. In some embodiments, forming the APHO film that covers the contact includes first, forming the APHO film so that the film covers the first drain/source contact of the FET, the gate of the FET, the second drain source contact of the FET, and the surface of the semiconductor substrate and second, etching the APHO film so that, with respect to the FET, the APHO film covers approximately only the gate contact and a portion of the surface over the channel region and not the first drain/source contact, the second drain/source contact, nor other portions of the surface of the semiconductor substrate of the FET. In some embodiments, the APHO film has a thickness of between 1 to 2 microns.

Any of the various features and elements as disclosed herein may be combined with one or more other disclosed features and elements, unless indicated to the contrary herein, together, and/or in various separate aspects and features as described herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an integrated circuit (IC) structure, in accordance with some embodiments;

FIG. 2 is a flow diagram that illustrates procedures for manufacturing the IC structure shown in FIG. 1, in accordance with some embodiments;

FIG. 3 is a flow diagram that illustrates procedures for forming the Aminated-Polyhydroxy organic (APHO) film shown in FIG. 1, in accordance with some embodiments; and

FIG. 4 is a flow diagram that illustrates procedures for forming the APHO film shown in FIG. 1, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Embodiments of an integrated circuit (IC) structure are disclosed. The IC structure includes an Aminated-Polyhydroxy organic (APHO) film that covers conductive contacts of active devices formed in a Front End of Line (FEOL) of a semiconductor substrate. The APHO film exhibits high moisture repelling properties, thus providing moisture ingress protection, a low dielectric constant (e.g., <2.5), and a high transition temperature (e.g., Tg≥300° C.). The APHO film prevents moisture from causing shorts and transient currents, thereby allowing high voltages to be applied to the contacts of active devices. Such protection can be achieved by the deposition of thin organic films that are pinhole free and able to conformally cover (i.e., coat) topography irregularities of the device architectures. Such thin films should also exhibit a low dielectric constant (e.g., <2.5) in order to be able to facilitate the propagation of high frequency signals within the circuits.

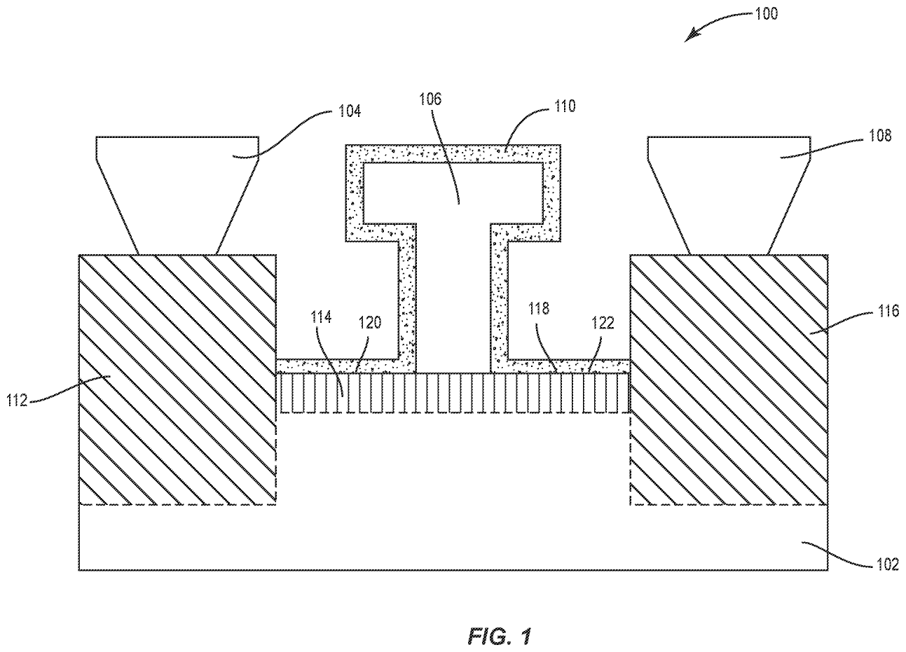

FIG. 1 illustrates an IC structure 100, in accordance with some embodiments.

The IC structure 100 includes a semiconductor substrate 102, contacts 104, 106, 108, and an APHO film 110. The APHO film 110 has a general chemical structure of {(—H2N═C . . . (═COH)x . . . }y. In some embodiments, the APHO film 110 is between 1 to 2 microns in thickness. In some embodiments, the APHO film 110 is deposited by a Chemical Vapor Deposition (CVD). The semiconductor substrate 102 defines active regions 112, 114, 116. The active regions 112, 114, 116 are regions that provide charge carrier exchanges in active semiconductor devices. The APHO film 110 allows for the semiconductor substrate 102 to be used to form active semiconductor devices in high voltage applications. The semiconductor devices exhibit moisture repelling properties of less than 10⁻⁴ grams per square meter per day of moisture permeation of Water Vapor Transmission Rates (WVTR). The APHO film 110 also has a dielectric constant less than or equal to 2.5. The APHO film 110 allows for high voltages (e.g., greater or equal to 40V) to be applied to the contacts 104, 106, 108 while not allowing moisture to short circuit the contacts 104, 106, 108. In some embodiments, the APHO film 110 has a thickness of between 1 to 2 microns. In some embodiments, the APHO film 110 has a glass-transition (Tg) temperature equal to or greater than 300° C. Accordingly, this allows for the semiconductor substrate 102 to be used in high frequency applications.

In some embodiments, the active region 112 operates as a drain/source region, the active region 114 is a channel region, and the active region 116 is a drain/source region in Front End of Line (FEOL) device structures. Thus, the contact 104 operates as a drain/source contact. In some embodiments, the contact 104 is provided in a VD conductive layer in a front end of Line (FEOL). In some embodiments, the contact 104 is made from a metal such as copper, gold, tin, or aluminum. The contact 106 operates as a gate contact. In some embodiments, the contact 106 is provided in a VG conductive layer in the FEOL. In some embodiments, the contact 106 is made from a conductive material such as copper, gold, tin, aluminum, or a conductive polysilicon. The contact 108 operates as a drain/source contact. In some embodiments, the contact 108 is provided in the VD conductive layer in the FEOL. In some embodiments, the contact 108 is made from a metal such as copper, gold, tin, or aluminum.

Thus, in some embodiments, the contacts 104, 106, 108 and the active regions 112, 114, 116 form a field effect transistor (FET). In some embodiments, the semiconductor substrate 102 is formed from a Group III-V semiconductor. In some embodiments, the semiconductor substrate 102 is formed from a silicon (Si), silicon carbide (SiC), gallium nitride (GaN), or gallium arsenide (GaAs) semiconductor. In some embodiments, the semiconductor substrate 102 includes GaN and/or GaAs semiconductor materials and is used in high power and high frequency applications. In some embodiments, the FET is a P-channel type FET. In some embodiments, the FET is an N-channel type FET.

The semiconductor substrate 102 defines a top surface 118. The contact 104 is positioned on the top surface 118 over the active region 112 so as to apply a voltage to the active region 112. In some embodiments, the contact 104 is a drain/source contact. The contact 106 is positioned on the top surface 118 over the active region 114 so as to apply a voltage to the active region 114. In some embodiments, the contact 106 is a gate (also referred to as a gate contact 106). The contact 108 is positioned on the top surface 118 over the active region 116 so as to apply a voltage to the active region 116. In some embodiments, intermediate layers are provided (such as dielectric layers) between the contacts 104, 106, 108 discussed herein and the top surface 118. In some embodiments, the contact 108 is a drain/source contact. The APHO film 110 has been etched to cover approximately only the contact 106 and portions 120, 122 of the top surface 118. The term “approximately” refers to covering only the contact 106 and the portions 120, 122 of the top surface 118 of the FET, as is within the known performance of manufacturing standards known for implemented manufacturing techniques. Thus, other portions may receive some slight covering of the APHO film 110 due to non-ideal deposition and etching in the manufacturing process. The portions 120, 122 of the top surface 118 are a top surface of the channel region 114. The portions 120, 122 are, thus, sensitive to moisture, which is particularly helpful in covering the portions 120, 122 in high frequency operations. Furthermore, the APHO film 110 covers the contact 106, which is a gate contact, which, thus, prevents shorts between the contact 106 and other portions of the FET.

The IC structure 100 shown in FIG. 1 is a FET. In some embodiments, the IC structure 100 may include multiple FETs, like the FET shown in FIG. 1. In some embodiments, the FETs are arranged in an array of FETs.

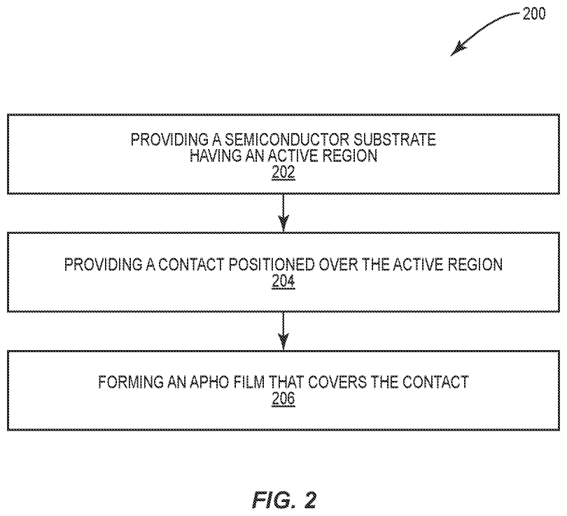

FIG. 2 is a flow diagram 200 that illustrates procedures for manufacturing the IC structure 100 shown in FIG. 1, in accordance with some embodiments.

The flow diagram 200 includes procedures 202, 204, 206. Flow begins at the procedure 202.

At the procedure 202, a semiconductor substrate is provided, the semiconductor substrate having an active region. An example of the semiconductor substrate is the semiconductor substrate 102 shown in FIG. 1. An example of the active region is the active region 114 shown in FIG. 1, in accordance with some embodiments. In some embodiments, the active region 114 is a channel region.

In some embodiments, the formation of source/drain regions in the substrate includes a portion of the substrate being removed to form recesses at an edge of each spacer and then performing a filling process by filling the recesses in the substrate. In some embodiments, the recesses are etched, for example, by using a wet etching or a dry etching, after removal of a pad oxide layer or a sacrificial oxide layer. In some embodiments, the etch process is performed in order to remove a top surface portion of the active region adjacent to an isolation region. In some embodiments, the filling process is performed by an epitaxy or epitaxial (epi) process. In some embodiments, the recesses are filled by using a growth process (which is concurrent with an etch process), where a growth rate of the growth process is greater than an etch rate of the etch process. In some embodiments, the recesses are filled by using a combination of growth processes and etch processes. For example, a layer of material is grown in the recess and then the grown material is subjected to an etch process to remove a portion of the material. Then, a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of a well is removed by an isotropic or an anisotropic etch process. The etch process selectively etches wells without etching into a gate structure or the spacers. In some embodiments, the etch process is performed using a reactive ion etch (RIE), a wet etch, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, a CVD process, a molecular beam epitaxy (MBE) process, other suitable processes, and/or a combination thereof. The epi process uses gaseous and/or liquidous precursors, which interact with a composition of the substrate. In some embodiments, the source/drain features include epitaxially grown silicon (epi Si), SiC, silicon germanium (SiGe), GaAs, or GaN. Source/drain regions of the IC device associated with the gate structure are in-situ doped or undoped during the epi process, in some instances. When the source/drain features are undoped during the epi process, the source/drain regions are doped during a subsequent process, in some instances. The subsequent doping process is achieved by an ion implantation, plasma immersion ion implantation, gas and/or solid source diffusion, other suitable processes, and/or a combination thereof. In some embodiments, source/drain regions are further exposed to annealing processes after forming source/drain regions and/or after the subsequent doping process. As discussed above, in some embodiments, the active region 114 is a channel region. In some embodiments, the active region 114 is formed using the processes discussed above. Flow then proceeds to the procedure 204.

At the procedure 204, a contact is provided and then positioned over the active region. The contact 106 in FIG. 1 is an example of the contact, in accordance with some embodiments.

In some embodiments, the contacts 104, 108 in FIG. 1 are drain/source contacts. In some embodiments, drain/source contacts are formed using a combination of photolithography and material removal processes to form openings in an insulating layer (not shown) over the semiconductor substrate 102. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, a laser drilling process, or another suitable etching process. The openings are then filled with conductive material (e.g., copper, aluminum, titanium, nickel, tungsten, or another suitable conductive material). In some embodiments, the openings are filled using CVD, plasma vapor deposition (PVD), sputtering, atomic layer deposition (ALD), or another suitable formation process.

In some embodiments, the contact 106 is a gate contact. In some embodiments, a gate dielectric material layer is deposited over the semiconductor substrate 102 below the contact 106. Example materials of the gate dielectric material layer include, but are not limited to, a high-k dielectric layer, an interfacial layer, and/or combinations thereof. In some embodiments, the gate dielectric material layer is deposited over the substrate by ALD or other suitable techniques. Other intermediate layers may also be provided. The gate contact 106 is deposited over the gate dielectric material layer (and other intermediate layers, in some embodiments). Example materials of the gate electrode layer include, but are not limited to, polysilicon, metal, aluminum (Al), AlTi, Ti, TiN, TaN, Ta, TaC, TaSiN, W, WN, MON, and/or other suitable conductive materials. Flow then proceeds to the procedure 206.

At the procedure 106, an APHO film that covers the contact is formed. An example of the APHO film is the APHO film 110 in FIG. 1, in accordance with some embodiments. In some embodiments, the APHO film 110 is deposited using plasma enhanced CVD (PECVD).

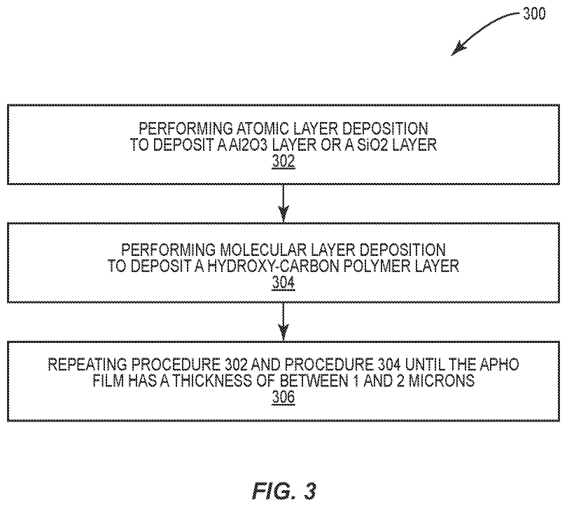

FIG. 3 is a flow diagram 300 the illustrates procedures for forming the APHO film 110 shown in FIG. 1, in accordance with some embodiments.

The flow diagram 300 includes procedures 302-306. Flow beings at the procedure 302. In some embodiments, the procedures 302-306 form the APHO film 110 pinhole free and conformally deposited.

At the procedure 302, ALD is performed to deposit Al₂O₃ layer or a SiO₂ layer. The Al₂O₃ layer or a SiO₂ layer is an inorganic sublayer. Flow then proceeds to the procedure 304.

At the procedure 304, molecular layer deposition (MLD) is performed to deposit a hydroxy-carbon polymer layer. The hydroxy-carbon polymer layer is an organic sublayer. The inorganic sublayer and the organic sublayer are bonded through covalent bonds, in accordance with some embodiments. The molecular weight of the hydroxy-carbon polymers can be between 20-500 Carboxy (C—OH) chains hydroxylated for surface activation. Flow then proceeds to the procedure 306.

At the procedure 306, the procedure 302 and the procedure 304 are repeated until the APHO film 110 until the APHO film 110 is between 1 and 2 microns in thickness. In other embodiments, the thickness of the APHO film 110 is any other adequate thickness. For example, in some embodiments, the APHO film 110 is between 2.5 microns and 3 microns in thickness. The composition of the organic layer and the inorganic layer are varied to meet specific electrical, optical, thermal, and mechanical properties. The so formed sandwiched layers of inorganic and organic layers can be formed in sequence of 3-10 consecutive layers of ALD-MLD deposition. In some embodiments, the number of such stack of inorganic and organic layers is 3-5.

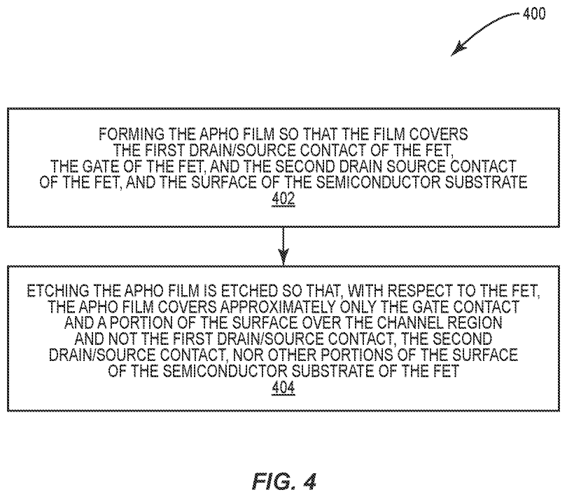

FIG. 4 is a flow diagram 400 that illustrates procedures for forming the APHO film 110 shown in FIG. 1, in accordance with some embodiments.

The flow diagram 400 includes procedures 402, 404. At the procedure 402, the APHO film is formed so that the film covers a first drain/source contact of a FET, a gate of the FET over a channel region of the FET, a second drain/source contact of the FET, and a surface of the semiconductor substrate, wherein the gate and the channel region are positioned between the first drain/source contact and the second drain/source contact. An example of the FET is shown in FIG. 1. An example of the surface is the top surface 118 in FIG. 1, in accordance with some embodiments. An example of the first drain/source contact is the contact 104 in FIG. 1. An example of the gate is the contact 106 in FIG. 1. An example of the second drain/source contact is the contact 108 in FIG. 1. An example of the channel region is the channel region 114 in FIG. 1. Flow then proceeds to the procedure 404.

At the procedure 404, the APHO film is etched so that, with respect to the FET, the APHO film 110 covers approximately only the gate contact and a portion of the surface over the channel region and not the first drain/source contact, the second drain/source contact, nor other portions of the surface of the semiconductor substrate of the FET. In some embodiments, the etching chemistries used to remove unprotected from photoresistant segments of the coated area are sulfur modified hydrofluorocarbon (HFC) gases. Examples of the HFC gases are: SF₆, SF₃, CF₄, CFH. These etchants are known to have different etch rates for the deposited ALD-MLD layers and a selectivity of etch processes. Any positive or negative tone photoresist can be used to provide sufficient resolution and to meet the Critical Dimension (CD) requirements for the structures to be etched. In some embodiments, the APHO film has a thickness between 1 to 2 microns.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. An integrated circuit (IC) structure, the IC structure comprising:
a semiconductor substrate having an active region;
a contact positioned over the active region; and
an Aminated-Polyhydroxy organic (APHO) film that covers the contact.

2. The IC structure of claim 1, wherein the APHO film has a chemical structure of {(—H2N═C . . . (═COH)ₓ . . . }_{y}.

3. The IC structure of claim 1, further comprising a second active region and a second contact, wherein:
the active region is a first active region;
the contact is a first contact;
the semiconductor substrate has the second active region;
the second contact is formed over the second active region; and
the APHO film does not cover the second contact.

4. The IC structure of claim 3, further comprising a third active region and a third contact, wherein:
the semiconductor substrate has the third active region;
the third contact is formed over the third active region;
the APHO film does not cover the third contact; and
the first active region is positioned between the second active region and the third active region.

5. The IC structure of claim 4, wherein:
the second active region is a first drain/source region;
the third active region is a second drain/source region;
the first active region is a channel region;
wherein the first active region, the second active region, the third active region, the first contact, the second contact, and the third contact form a field effect transistor (FET);
wherein the semiconductor substrate defines a top surface; and
wherein, with respect to the FET, the APHO film covers approximately only the first contact and portions of the top surface of the channel region but not the second contact, the third contact, nor other portions of the top surface for the FET.

6. The IC structure of claim 4, wherein the first contact is a second metallic contact, the third contact is a second metallic contact, and the first contact is a gate contact.

7. The IC structure of claim 4, wherein:
the first contact is formed on the first active region;
the second contact is formed on the second active region; and
the third contact is formed on the third active region.

8. The IC structure of claim 1, wherein the APHO film exhibits moisture repelling properties of less than 10⁻⁴ grams per square meter per day.

9. The IC structure of claim 8, wherein the APHO film has a thickness of between 1 and 2 microns.

10. The IC structure of claim 1, wherein the APHO film has a thickness of between 1 and 2 microns.

11. The IC structure of claim 1, wherein the APHO film has a dielectric constant less than or equal to 2.1.

12. The IC structure of claim 1, wherein the APHO film has a transition temperature equal to or greater than 250 degrees Celsius.

13. A method of manufacturing an integrated circuit (IC) structure, the method comprising:
providing a semiconductor substrate having an active region;
providing a contact positioned over the active region; and
forming an Aminated-Polyhydroxy organic (APHO) film that covers the contact.

14. The method of claim 13, wherein forming the APHO film that covers the contact comprises:
(a) performing atomic layer deposition (ALD) to deposit an Al₂O₃ layer or a SiO₂ layer; or
(b) performing molecular layer deposition (MLD) to deposit a hydroxy-carbon polymer layer.

15. The method of claim 14, further comprising:
repeating (a) and (b) until the APHO film has a thickness of between 1 and 2 microns.

16. The method of claim 13, wherein:
the active region is a channel region; and
the contact is a gate contact.

17. The method of claim 16, wherein the APHO film further covers a portion of a top surface of the semiconductor substrate over the channel region.

18. The method of claim 13, wherein:
the semiconductor substrate defines a surface;
the active region is a channel region;
the contact is a gate contact formed over the channel region;
the semiconductor substrate defines a first drain/source region and a second drain/source region;
a first drain/source contact is formed over the second drain/source region;
a second drain/source contact is formed over the first drain/source region;
wherein the channel region is positioned between the first drain/source region and the second drain/source region;
wherein the first drain/source region, the first drain/source contact, the second drain/source region, the second drain/source contact, the channel region, and the gate contact form a field effect transistor (FET).

19. The method of claim 18, wherein forming the APHO film that covers the contact comprises:
forming the APHO film so that the AHPO film covers the first drain/source contact of the FET, the gate contact of the FET, the second drain/source contact of the FET, and the surface of the semiconductor substrate; and
etching the APHO film so that, with respect to the FET, the APHO film covers approximately only the gate contact and a portion of the surface over the channel region and not the first drain/source contact, the second drain/source contact, nor other portions of the surface of the semiconductor substrate of the FET.

20. The method of claim 19, wherein the APHO film has a thickness of between 1 and 2 microns.
